(19) United States
(12) Patent Application Publication
(10) Pub. No.: US 2012/0111399 A1
(43) Pub. Date: May 10, 2012

(54) SOLAR CELL ELECTRODE

(75) Inventor: Takeshi Kondo, Kanagawa (JP)

(73) Assignee: E. I. DU PONT DE NEMOURS AND COMPANY, Wilmington, DE (US)

(21) Appl. No.: 12/941,433

(22) Filed: Nov. 8, 2010

(51) Int. Cl. H01L 31/0224; H01L 31/18

(52) U.S. Cl. 136/256; 438/98; 257/E31.124

(57) ABSTRACT

A method for forming a solar cell electrode, comprising the steps of: applying a conductive paste comprising an organic binder and inorganic components comprising conductive powder and glass frit onto a passivation layer with at least 200 nm thickness formed on one surface or on both front and back surfaces of a silicon substrate, wherein the softening point of the glass frit is 395° C. or lower; and firing the conductive paste applied onto the passivation layer.

### BACKGROUND OF THE INVENTION

1. Field of the Invention

This invention relates to a solar cell, specifically an electrode used in a solar cell.

2. Description of Related Art

The fire-through method, in which a conductive paste as a electrode material is applied and fired on a passivation layer which is formed on a silicon substrate, is known for forming a silicon solar cell electrode. This formation process exploits a phenomenon whereby the passivation layer is ruptured during the firing process by the action of glass powder added to the conductive paste, and an ohmic contact is formed between the n⁺ layer and the metal components in the conductive paste (cf. JP 2001-313400). The components of the conductive paste for forming the electrode are essential for achieving fire-through. Passivation layers are primarily formed either to prevent reflection of incident light as an anti-reflection layer (ARC), or to reduce recombination, in which electrons and holes on the substrate surface join and are eliminated, and have conventionally been no more than a few tens of nm thick. In recent years, however, solar cells have been developed with passivation layers 200 nm or more thick in order to protect the semiconductor layer (cf. JP 2006-287027).

When the fire-through method has been attempted with such a thick passivation layer, there have been problems of insufficient fire-through and increased contact resistance between the electrode and the silicon substrate. In general, fire-through can be accomplished by raising the firing temperature, but if the temperature is too high, the silicon substrate is damaged. Rather than firing through, another possibility is to provide grooves in the passivation layer and form the electrode in the grooves, thereby creating a direct contact between the silicon substrate and the electrode. However, this method involves complex processing.

An electrode needs to fire through a passivation layer as mentioned above, and also in an embodiment not reach the p-n junction of the silicon substrate in order to obtain contact resistance without shunting the p-n junction.

### BRIEF SUMMARY OF THE INVENTION

It is an object to provide a method for forming a solar cell electrode whereby adequate fire-through is achieved with a passivation layer 200 nm or more thick without raising the firing temperature, and contact resistance is minimized.

The process for forming a solar cell electrode comprises steps of: applying a conductive paste comprising an organic binder and inorganic components comprising conductive powder and glass frit onto a passivation layer with at least 200 nm thickness formed on one surface or on both front and back surfaces of a silicon substrate, wherein the softening point of the glass frit is 395° C. or lower; and

firing the conductive paste applied onto the passivation layer.

In another aspect, an electrode for a solar cell is formed by the process for forming a solar cell electrode described above.

It becomes possible to obtain a solar cell electrode that is fired through and whereby contact resistance with the silicon substrate can be minimized even though the electrode is formed on a passivation layer 200 nm or more thick, and to improve the electrical characteristics of a solar cell.

### BRIEF DESCRIPTION OF THE DRAWINGS

FIG. 1A is a cross-sectional schematic drawing of a back contact type solar cell.

FIG. 1B is an overhead view showing an electrode pattern on a side opposite from a light receiving side of a back contact type solar cell.

FIG. 2A to 2E are drawings for explaining a method of forming of n layer of a back contact type solar cell.

FIG. 3A to 3E are drawings for explaining a method of forming of p layer of a back contact type solar cell.

FIG. 4A to 4D are drawings for explaining a method of forming of texturing on a light receiving side of a back contact type solar cell.

FIG. 5A to 5C are drawings for explaining a method of forming an electrode of a back contact type solar cell.

FIG. 6A to 6F are drawings for explaining a method of forming a solar cell having an electrode on a light receiving side.

FIG. 7A is drawings for shape of a sample for measuring contact resistance of an electrode on Si substrate in Example.

FIG. 7B is a drawing for explaining resistance values measured between electrodes in Example.

### DETAILED DESCRIPTION OF THE INVENTION

Embodiments are explained below with reference to the drawings. The embodiments given below are only examples, and appropriate design changes are possible for those skilled in the art.

### (A) Back-Contact Type PV Electrode Production Process

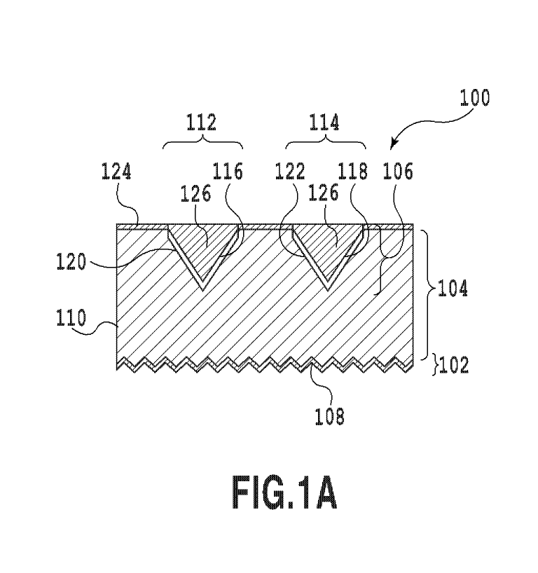

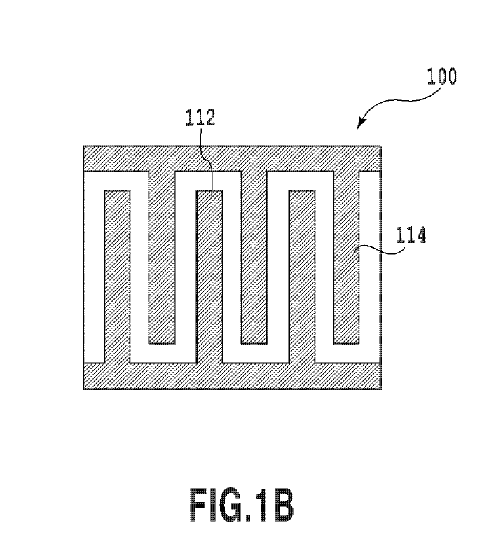

In an embodiment, the electrode-forming method can be used for a back contact-type solar cell having both an N-layer and a P-layer on a reverse side of a light-receiving side, and an electrode in contact with these layers. In a back contact-type solar cell, both the light-receiving side and the reverse side of a light-receiving side have passivation layers. The following provides an explanation of a back contact-type solar cell and an explanation of a production process of back contact-type solar cell electrodes as an example, as shown in FIG. 1, while also providing an explanation of an example of the fabrication of a solar cell.

FIG. 1A is a cross-sectional drawing of a portion of a back contact-type solar cell. FIG. 1B is an overhead view showing an electrode pattern on an opposite side from a light receiving side. A back contact-type solar cell 100 is composed of a light receiving section 102, a carrier generating section 104 and an electrode section 106. The light receiving section 102 has a textured structure, and the surface thereof is covered with a passivation layer 108. As a result of the light receiving section 102 having a textured structure covered by this passivation layer 108, more incident light enters the carrier generating section 104, thereby making it possible to increase the conversion efficiency of the solar cell 100.

The carrier generating section 104 is composed of a semiconductor 110. When light from the light receiving section 102 (and particularly light having energy equal to or greater than the band gap of the semiconductor 110) enters this semiconductor 110, valence band electrons are excited to the conduction band, free electrons are generated in the conduction band, and free holes are generated in the valence band. These free electrons and free holes are referred to as carriers. If these carriers reach the electrode section 106 by diffusion prior to being recombined in the carrier generating section 104, a current can be obtained from the electrode section 106. Thus, in order to increase the conversion efficiency of the solar cell 100, a semiconductor that impairs carrier recombination (namely, has a long carrier life) is used in an embodiment. For this reason, the semiconductor 110 used in the carrier generating section 104 is, for example, crystalline silicon.

The electrode section 106 is a section where current generated in the carrier generating section 104 is obtained. This electrode section 106 is formed on the opposite side from the side of the light receiving section 102 of the semiconductor 110. The electrode section 106 has an anode 112 and a cathode 114, and these are alternately formed on the opposite side from the side of the light receiving side 102 of the semiconductor 110. The anode 112 and the cathode 114 are respectively formed in the form of V grooves 116 and 118 having triangular cross-sections. p-layer 120 is formed in the V groove 116 of the anode 112, while an n-layer 122 is formed in the V groove 118 of the cathode 114. The surface of the back side of the light receiving side 102 is covered with a passivation layer 124. In addition, electrodes 126 formed from the conductive paste are embedded in the V grooves.

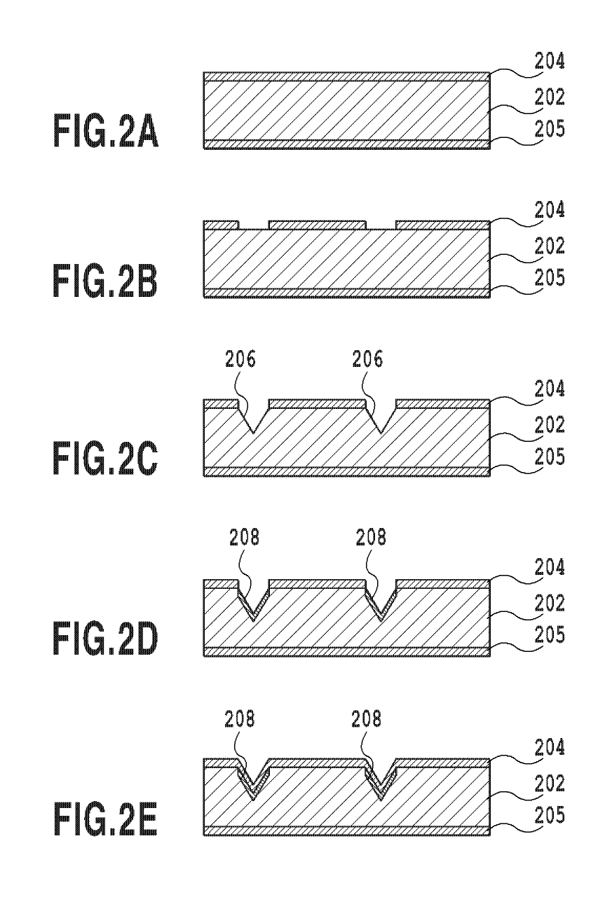

Next, an explanation is provided of the production process of a back contact-type solar cell electrodes along with an explanation of the production process of a back contact-type solar cell with reference to from FIG. 2 to FIG. 5.

(A-1) Preparation of n-Layer

A silicon substrate 202 is prepared, and passivation layers 204 and 205 are formed on both sides thereof (FIG. 2A). Silicon nitride (SiNx), Titanium oxide (TiO₂), Aluminum oxide (Al₂O₃), Silicon oxide (SiOx), Ta₂O₅, or Indium Tin Oxide (ITO) can be used as a material for forming a passivation layer 204 and 205.

A passivation layer of SiOx can be formed on a silicon substrate by a process such as plasma-enhanced chemical vapor deposition (PECVD).

An aluminum oxide or titanium oxide layer can be formed by atomic layer deposition (ALD) method. A titanium oxide layer can also be formed by thermal CVD method, in which thermal decomposition is performed at from 250 to 300° C. using a mixture of a water vapor and a vapor of an organic titanate (organic liquid material containing titanium) such as TPT (tetrapropyl titanate).

A silicon oxide layer can be formed by thermal oxidation method, for example, by thermal CVD method or plasma CVD method. In the case of thermal CVD method, it can be formed at a temperature of 700 to 900° C. using a mixed gas of Si₂Cl₄ and O₂ for example as the raw material gas. In the case of plasma CVD method, it can be formed at a temperature of 200 to 500° C. using a mixed gas of SiH₄ and O₂ for example as the raw material gas. A silicon oxide layer can also be formed by wet oxidation method using nitric acid.

The passivation layer may also have a multilayered structure. For example, the passivation layer may be made with a two-layer structure by forming a TiO₂ layer, Al₂O₃ layer or SiOx layer on top of the p-layer, and then forming a silicon nitride layer on top of this oxide film.

The thickness of the passivation layer is 200 nm or more, although it can be adjusted according to the properties or manufacturing conditions of the solar cell.

Next, the passivation layer 204 on one side of the silicon substrate is removed by photolithography or laser etching and so on to leave stripes of a predetermined width (for example, width of 100 μm and interval of 300 μm) (FIG. 2B).

Next, anisotropic etching is carried out with potassium hydroxide (KOH) or tetramethyl ammonium hydroxide (TMAH) on the side from which a portion of the oxide layer has been removed, to form V grooves 206 (at an interval of, for example, 300 μm) in the form of stripes having a triangular cross-section (FIG. 2C).

Next, the substrate in which the V grooves 206 have been formed is placed in a diffusion furnace to diffuse the phosphorous. As a result of these steps, an n-layer 208 is formed on the portions of the silicon where the V grooves 206 have been formed as shown in FIG. 2D.

An additional passivation layer is then formed on the n-layer 208 in accordance with the method as described above (FIG. 2E). For example, in the diffusion furnace, by interrupting the gas serving as the phosphorous material and introducing only oxygen, the surfaces of the V grooves 206 can be covered with a silicon oxide layer as a passivation layer. An additional passivation layer can also be formed by CVD method or the like on the n-layer. In this case, the additional passivation layer can be formed only on the p-layer, or can be prepared so as to cover the original passivation layer.

(A-2) Preparation of p-Layer

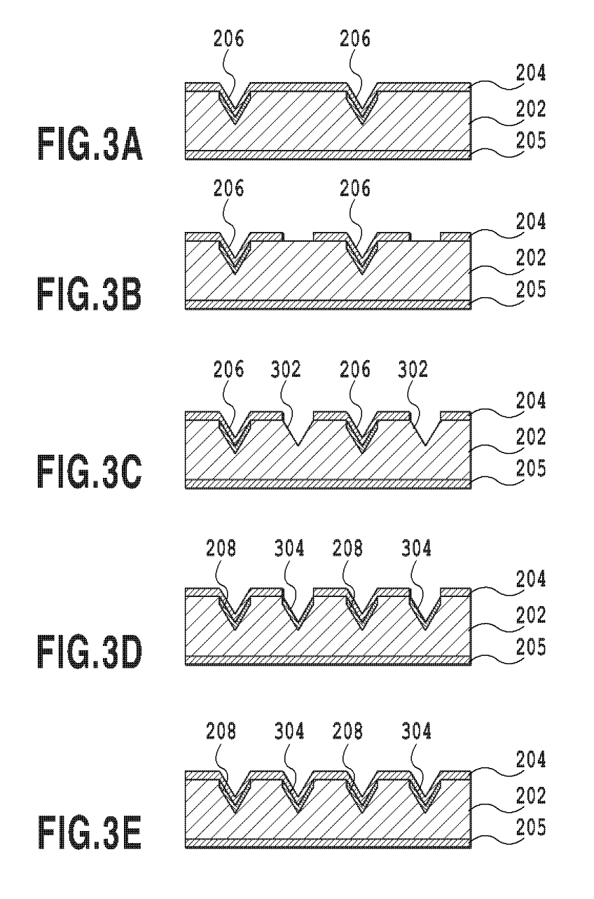

The passivation layer 204 is then removed from the substrate obtained in this manner (FIG. 3A) at equal intervals by photolithography or laser etching at the portions between the V grooves 206 of the passivation layer 204 (FIG. 3B). For example, in the case the passivation layer portion between the newly formed V grooves 206 has a width of 300 μm, the passivation layer is removed so that the distance from the V grooves 206 on both sides of this passivation layer portion is 100 μm.

Next, anisotropic etching is carried out with potassium hydroxide (KOH) or tetramethyl ammonium hydroxide (TMAH) and so on at those locations where the passivation layer has been removed to form V grooves 302 in the form of stripes having a triangular cross-section (FIG. 3C).

Next, the substrate in which the V grooves 302 have been formed is placed in a diffusion furnace to diffuse boron. As a result, as shown in FIG. 3D, a p-layer 304 is formed on the silicon portions of the V grooves.

An additional passivation layer is then formed on the p-layer 304 in accordance with the method as described above (FIG. 3E). For example, in the diffusion furnace, by interrupting the gas serving as a boron material and introducing oxygen only, the surfaces of the V grooves can be covered with a passivation layer.

The passivation layers are formed in the multiple steps as explained above, and the passivation layer 204 formed on the undoped silicon layer may have a different thickness from passivation layer 204 formed on the n-layer and/or p-layer. However, the thickness of the final passivation layer 204 is at least 200 nm. The passivation layer is made thicker than usual for the purpose of controlling interference color and improving external appearance, as well for controlling leakage current. For these purposes, the thickness of the passivation layer is at least 300 nm in an embodiment. As for the upper limit on the thickness, the passivation layer does not exceed 1600 nm in an embodiment, and does not exceed 1400 nm in another embodiment.

### (A-3) Texturing of the Light-Receiving Layer

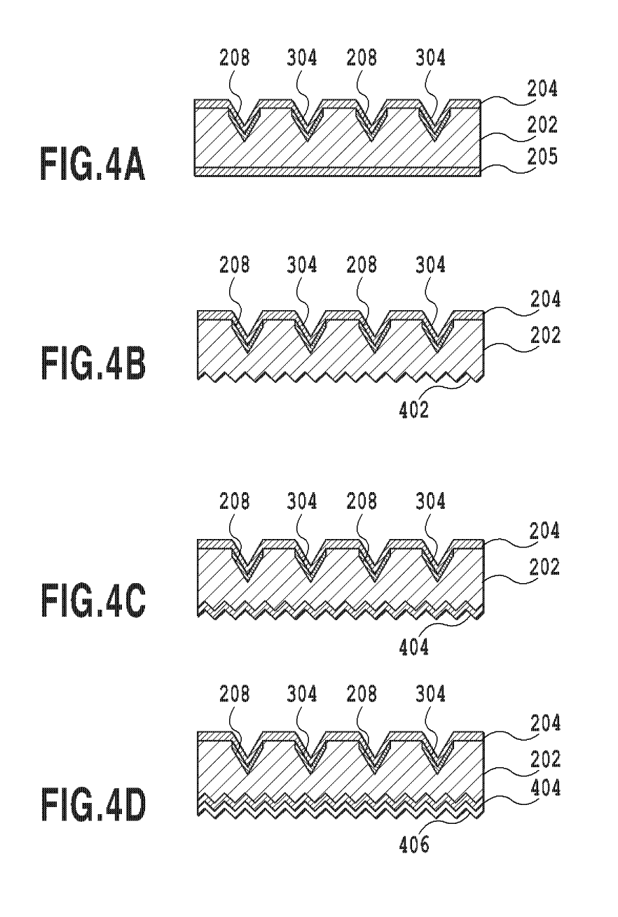

After removing the passivation layer 205 on the light receiving side of the silicon substrate 202 (FIG. 4A), anisotropic etching is carried out with potassium hydroxide (KOH) or tetramethyl ammonium hydroxide (TMAH) and so on to form a textured structure 402 in the form of stripes having a triangular cross-section (FIG. 4B). By then carrying out dry oxidation in a diffusion furnace, a silicon oxide layer 404 is formed on the light receiving side of the substrate (FIG. 4C).

Subsequently, titanium dioxide (TiO₂), for example, is then deposited on the silicon oxide layer 404 at normal temperatures by sputtering. The formed silicon oxide layer 404 and titanium dioxide layer 406 can function as passivation layers. As a result, a light receiving side having passivation layers with a textured structure is formed on the other side of the substrate (FIG. 4D).

### (A-4) Electrode Preparation

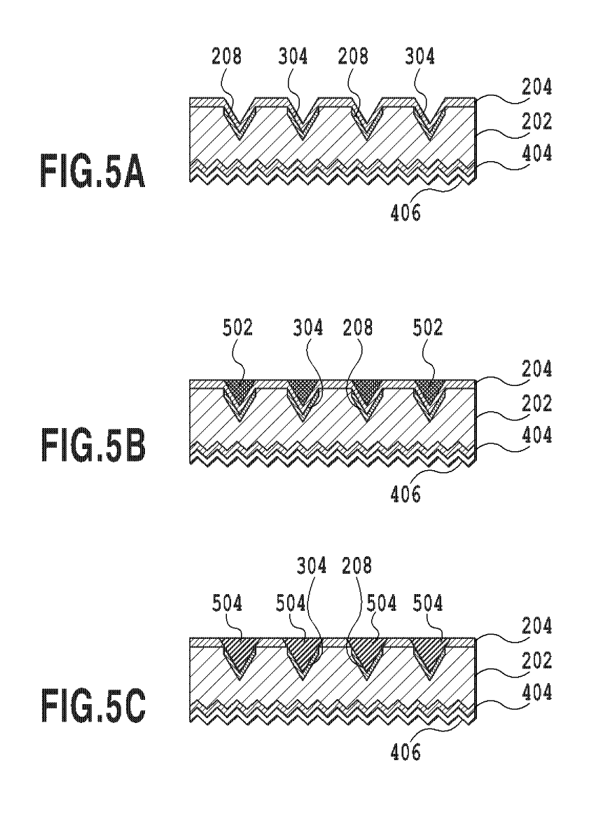

Next, electrodes are formed using a conductive paste. In this step, the conductive paste 502 is embedded in the V grooves of the substrate (FIGS. 5A and 5B). Embedding of the conductive paste can be carried out by a patterning method such as screen printing, stencil printing or dispenser applying.

Next, the substrate filled with the conductive paste in the V grooves is fired at a predetermined temperature (for example, from 450 to 900° C.) (FIG. 5C). As a result, the conductive paste is sintered and fired through the passivation layer to make a contact between the formed electrode 504 and the p-layer 304 or n-layer 208.

### (B) Method for Forming Solar Cell Electrode Having Front Contact

In another embodiment, the electrode-forming method can be applied to a solar cell having an electrode at least on the light-receiving side (front side). A solar cell having such a front contact may be of a type having a passivation layer formed only on the front side surface, or a type having layers formed on both the front and back side surfaces. Either type is applicable. Because a solar cell having a front contact normally also has an electrode on the reverse side opposite the light-receiving side (back side), the invention can also be applied to either the front contact or the back contact or both in the case of the type having passivation layers formed on both the front and back surfaces. In the type having a passivation layer formed only on the front surface, the invention can only be applied to forming the front contact.

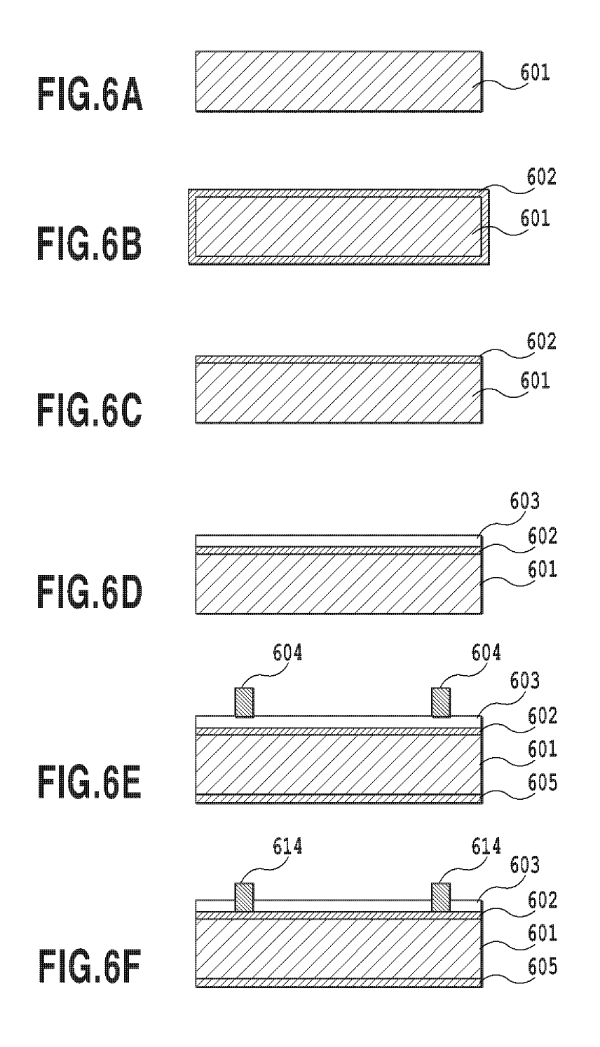

When forming a solar cell electrode at the front side of a solar cell, the substrate, passivation layer and conductive paste can be same as those used for the aforementioned back contact type solar cell. The method for forming a solar cell electrode is explained below with reference to FIGS. 6A to 6F using the example of a P-type base solar cell having a front contact.

FIG. 6A shows a p-type silicon substrate 601.

In FIG. 6B, an n-layer 602, of the reverse conductivity type is formed by the thermal diffusion of phosphorus (P) or the like. Phosphorus oxychloride (POCl₃) is commonly used as the phosphorus diffusion source. In the absence of any particular modification, n-layer 602 is formed over the entire surface of the silicon substrate 601. The silicon wafer consists of p-type substrate 601 and n-layer 602 typically has a sheet resistivity on the order of several tens of ohms per square (Ω/° C.). After protecting one surface of the n-layer with a resist or the like (not shown in FIGS. 6B and 6C), the n-layer 602 is removed from most surfaces by etching so that it remains only on one main surface as shown in FIG. 6C. The resist is then removed using an organic solvent or the like. Next, a passivation layer 603 is formed on the n-layer 602 as shown in FIG. 6D.

In the type having a front contact, the thickness of the passivation layer 603 formed on the n-layer is at least 200 nm. This serves to control interference color of the passivation layer, improve external appearance and also control leakage current. For these purposes, the thickness of the passivation layer is at least 300 nm in an embodiment. As for the upper limit on the thickness, the passivation layer does not exceed 1600 nm in an embodiment, and does not exceed 1400 nm in another embodiment.

As shown in FIG. 6E, a conductive paste is screen printed on the passivation layer 603 with a desired pattern. The printed conductive paste 604 is then dried. A conductive paste is then screen printed on the backside of the substrate 601. The back side conductive layers may be two layers which comprise different metal respectively. The printed conductive paste 605 is successively dried. The dried paste is fired at peak temperature of 450 to 900° C.

By means of this firing, the conductive paste is sintered and fired through, and electrode 614 (FIG. 6F) is formed.

In another embodiment, a conductive paste described above can be applied to the back side of the light receiving side of the substrate to form back electrode when the substrate has a passivation layer at the back side too.

The method for forming a solar cell electrode can be applied even to the electrode of an N-type base solar cell in which the substrate 601 is an n-type silicon substrate. For a manufacturing of n-type silicon, the following references can be referred to. They are herein incorporated by reference.
A. Weeber et al. Status of N-type Solar Cells for Low-Cost Industrial Production; Proceedings of 24 th European Photovoltaic solar Energy Conference and Exhibition, 21-25 Sep. 2009, Hamburg, Germany
J. E. Cotter et al., N-type versus n-type Silicon Wafers: Prospects for hi-efficiency commercial silicon solar cell; IEEE transactions on electron devices, VOL. 53, No. 8, August 2006, pp 1893-1896.

When a passivation layer is formed on the light-receiving side of the silicon substrate, it may also be called an anti-reflection coating (ARC) in consideration of its light reflection-preventing function.

Next, the conductive paste used in the method for forming a solar cell electrode is explained in detail. The conductive paste used in the method for forming a solar cell electrode contains inorganic components including a) conductive powder and b) glass frit, and an organic binder. In this application, “inorganic component” is conductive powder, glass frit, and any other component, which is optionally added, containing no carbon. When allotropes of carbon such as graphite or carbide containing precious metal, base metal, alkali metal, alkaline earth metal and semimetal is added to the conductive paste, they can be also considered as an inorganic component. Hydrocarbon is excluded from the definition of inorganic component.

### 1. Conductive Powder

The conductive powder is a metal powder or alloy powder having electrical conductivity of 1.00×10⁷ Siemens (S)/m or more at 20° C. Such metals are for example iron (Fe; 1.00×10⁷ S/m), aluminum (Al; 3.64×10⁷ S/m), nickel (Ni; 1.45×10⁷ S/m), copper (Cu; 5.81×10⁷ S/m), silver (Ag; 6.17×10⁷ S/m), gold (Au; 4.17×10⁷ S/m), molybdenum (Mo; 2.10×10⁷ S/m), magnesium (Mg; 2.30×10⁷ S/m), tungsten (W; 1.82×107 S/m), cobalt (Co; 1.46×10⁷ S/m), and zinc (Zn; 1.64×10⁷ S/m) (Japan Institute of Metals (2005), p. 221). In an embodiment, a metal or alloy with a conductivity of 3.00×10⁷ S/m or more is used. More specifically, aluminum, copper, silver or gold is used. By using a conductive powder with high conductivity, it is possible to improve the light conversion efficiency of the solar cell. Silver is used in an embodiment since it resists oxidation during the firing process.

The conductive powder may be in the shape of flakes, spheres or they may be amorphous. Although there are no particular limitations on the particle diameter of the conductive powder from the viewpoint of technical effects in the case of being used as an ordinary conductive paste, particle diameter has an effect on the firing characteristics of the conductive powder, for example, conductive powder having a large particle diameter are fired at a slower rate than conductive powder having a small particle diameter. Thus, the particle diameter (d₅₀, determined with a laser scattering-type particle size distribution measuring apparatus) is within the range of 0.1-20.0 μm in an embodiment, 1.0-10.0 μm in another embodiment, or 1.0 to 5.0 μm in further another embodiment. The particle diameter of the conductive powder actually used is determined according to the firing profile. Moreover, in an embodiment, the conductive powder has a particle diameter suited for methods for applying an conductive paste (for example, screen printing). Two or more types of conductive powder having different particle diameters may be used as a mixture.

Normally, the conductive powder has a high purity greater than 98%. However, substances of lower purity can be used depending on the electrical requirements of the electrode pattern.

Although there are no particular limitations on the conductive powder content, in the case of conductive powder, the conductive powder content is 30-98 wt % in an embodiment, and 50-90 wt % in another embodiment based on the total weight of the inorganic components.

### 2. Glass Frit

The glass frit is powdered glass comprising multiple inorganic raw materials. When the conductive paste is fired, the glass frit has the function of assisting sintering of the conductive powder and promoting fire-through. The glass frit also serves the function of making the electrode stick to the substrate.

The glass frit has 395° C. or lower of softening point. If the softening point is below 395° C., contact resistance is controlled as shown in the examples below. The glass frit has a softening point of 380° C. or less in an embodiment, 340° C. or less in another embodiment, and 320° C. or less in further another embodiment. As shown in Examples 1 to 3, the resistance tends to be lower when the softening point of the glass frit is lower. There is no particular lower limit to the glass frit softening point. A glass frit softening point of 300° C. or more is practical from the standpoint of ease of manufacture.

In this specification, “softening point” is determined by differential thermal analysis (DTA). To determine the glass softening point by DTA, sample glass is ground and is introduced with a reference material into a furnace to be heated at a constant rate of 5 to 20° C. per minute. The difference in temperature between the two is detected to investigate the evolution and absorption of heat from the material. In general, the first evolution peak is on glass transition temperature (Tg), the second evolution peak is on glass softening point (Ts), the third evolution peak is on crystallization point. When a glass frit is a noncrystalline glass, the crystallization point would not appear in DTA.

In another embodiment, the glass frit may be a noncrystalline glass and keep noncrystalline phases upon firing at 800° C. or lower. In this specification, “noncrystalline glass” is determined by DTA as described above. The third evolution peak would not appear upon firing at 0-800° C. in a noncrystalline glass DTA.

The glass frit composition is not particularly limited, but because it has a low softening point, Pb-base glass or Bi-base glass is used in an embodiment. In general, a Pb compound or Bi compound is effective for lowering the glass softening point.

In an embodiment, the glass frit is Pb-base glass. The Pb-base glass includes a Pb compound in an amount of 60-92 wt % in an embodiment, 70-90 wt % in another embodiment, and 75-88 wt % in further another embodiment. The Pb compound may contain only PbO, or may comprise both PbO and PbF₂. When it contains both PbO and PbF₂, the PbF₂ constitutes 5-40 wt % in an embodiment, and 10-35 wt % in another embodiment based on the total weight of the Pb compound.

The Pb-base glass may also contain one or two or more oxides selected from SiO₂, Al₂O₃ and ZrO₂. When these oxides are included, the contents of each can be as follows as a percentage of the total glass weight. The SiO₂ content is 10-30 wt % in an embodiment, 10-20 wt % in another embodiment, 10-15 wt % in further another embodiment. The Al₂O₃ content is 0.1-2.0 wt % in an embodiment, 0.15-1.5 wt % in another embodiment, 0.2-1.0 wt % in further another embodiment. The ZrO₂ content is 0.1-2.0 wt % in an embodiment, 0.15-1.5 wt % in another embodiment, 0.2-1.0 wt % in further another embodiment.

The Pb-base glass frit may also contain one or two or more oxides selected from K₂O, Na₂O and Li₂O. When these oxides are contained, the contents of each (as a percentage of the total glass weight) are as follows. K₂O is 0.01-20 wt % in an embodiment, 0.1-15 wt % in another embodiment. Na₂O is 0.01-10 wt % in an embodiment, 0.03-8 wt % in another embodiment. Li₂O is 0.05-5 wt % in an embodiment, 0.1-3 wt % in another embodiment.

In another embodiment, the glass frit is Bi-base glass. Bi-base glass contains 20-80 wt % of Bi₂O₃ in an embodiment, and 40-60 wt % Bi₂O₃ in another embodiment based on the total weight of the glass.

Bi-base glass may also contain either SiO₂ or B₂O₃, or both oxides. When these oxides are included, the contents of each can be as follows as a percentage of the total weight of the glass. SiO₂ is 5-50 wt % in an embodiment, 10-30 wt % in another embodiment. B₂O₃ is 1-10 wt % in an embodiment, 2-4 wt % in another embodiment.

The Bi-base glass frit may also contain one or two or more oxides selected from BaO, Al₂O₃ and TiO₂. When these oxides are included, the contents of each can be as follows as a percentage of the total weight of the glass. BaO is 0.1-20 wt % in an embodiment, 0.1-10 wt % in another embodiment. Al₂O₃ is 0.1-25 wt % in an embodiment, 0.1-15 wt % in another embodiment. TiO₂ is 0.1-25 wt % in an embodiment, 0.1-15 wt % in another embodiment.

The Bi-base glass frit may also contain one or two or more oxides selected from K₂O, Na₂O and Li₂O. When these oxides are contained, the contents of each are as follows as a percentage of the total weight of the glass. K₂O is 0.01-20 wt % in an embodiment, 0.1-15 wt % in another embodiment. Na₂O is 0.01-10 wt % in an embodiment, 0.03-8 wt % in another embodiment. Li₂O is 0.05-5 wt % in an embodiment, 0.1-3 wt % in another embodiment.

The definitions of Pb-base glass and Bi-base glass here do not exclude glass containing Bi compounds and Pb compounds, respectively, and Pb-base glass may contain Bi compounds, while conversely Bi-base glass may contain Pb compounds.

Although there is no particular limitation on a content of the glass frit in the conductive paste, the glass frit is 0.5-15 wt % in an embodiment, 2-12 wt % in another embodiment, and 3-10 wt % in further another embodiment, based on the total weight of the inorganic components. If the amount of the inorganic binder is less than 0.5% by weight, adhesive strength may become inadequate. If the amount of glass frit exceeds 15 wt % by weight, the resistance value as a conductor might increase.

### 3. Organic Binder

The conductive paste to make an electrode contains an organic binder to render printability to conductive paste. The organic binder is a resin or a mixture of a resin and a solvent. Any arbitrary resin can be used.

As a kind of resin, for example, an epoxy resin, polyester resin, an ethylene-vinyl acetate copolymer, and modified cellulose, such as polyvinyl chloride acetate copolymer, phenol resin, acrylic resin, ethyl cellulose, or nitrocellulose, is mentioned. The ethyl cellulose with good solvent solubility is used in an embodiment.

A solvent can be additionally used as a viscosity adjuster as necessary. Any arbitrary solvent can be used. Examples of the solvent include aromatic, ketone, ester, ether, glycol, glycol ether and glycol ester. In case of screen printing is taken, high-boiling solvent such as ethyl carbitol acetate, butyl cellosolve acetate, cyclohexanone, benzyl alcohol, or terpineol is favorably used.

The organic binder is, in an embodiment, 10-50% by weight based on the total weight of the paste.

### 4. Additional Metal/Metal Oxide Powder

In an embodiment, the conductive paste may optionally contain an additional metal/metal oxide powder. The additional metal/metal oxide powder can be selected from (a) a metal selected from Zn, Ti, Mn, Sn, Mo, In and Cu; (b) an oxide of the metal (a); and (c) a mixture thereof. The additional metal/metal oxide powder can be more selected from (a) a metal selected from Zn, Ti and Sn; (b) an oxide of the metal (a); and (c) mixtures thereof in an embodiment. The additional metal/metal oxide powder can be Zinc oxide (ZnO) in an embodiment.

The additional metal/metal oxide powder content is 0.5-15.0 wt % in an embodiment based on the total weight of the inorganic components in the conductive paste. If there is too much additional metal/metal oxide powder, the contact resistance value tends to rise as shown in the examples below. The additional metal/metal oxide powder content is 1.0-10.0 wt % in an embodiment, 2.0-7.0 wt % in another embodiment. The specific surface area (SA) of the particles of the additional metal/metal oxide powder is not particular limited but is 0.1 m²/g or more in an embodiment, more 1.2 m²/g or more in another embodiment. If the SA is too small, it might be difficult to apply to the substrate, because the particles size might be too large. The specific surface area (SA) of the additional metal/metal oxide powder particles does not exceed 100 m²/g. This is because if the SA is too large the particles may be too small, and they may remain disproportionately in the paste rather than dispersing in the organic binder.

From the standpoint of dispersibility, the specific surface area (SA) of the additional metal/metal oxide powder particles does not exceed 50 m²/g in an embodiment, does not exceed 20 m²/g in another embodiment, and does not exceed 5 m²/g in further another embodiment.

In an embodiment, the additional metal/metal oxide powder is zinc oxide (ZnO). ZnO is a compound resulting from the reaction of zinc and oxygen, and is a white powder material having a hexagonal wurzite crystal structure. ZnO is 2-8 wt % in an embodiment, 3-5 wt % in another embodiment based on based on the total weight of the inorganic components in the conductive paste.

### 5. Additives

A thickener, stabilizer, dispersants, viscosity adjuster or mixture thereof may be added to the conductive paste to make the electrode. The amount of additive is determined dependent upon the characteristics of the ultimately required conductive paste. The amount of additive can be suitably determined by a person with ordinary skill in the art.

The conductive paste can be produced by mixing each of the above-mentioned components with a roll mixing mill or rotary mixer and the like.

The conductive paste is applied onto a passivation layer on a Si wafer of a solar cell by screen printing in an embodiment. In case of screen printing, the viscosity of the conductive paste is, in an embodiment, 50 to 400 Pa·s with a #14 spindle with a Brookfield HBT viscometer and measuring using a utility cup at 10 rpm and 25° C.

Although the amount of viscosity adjuster added changes dependent upon the viscosity of the ultimate conductive paste, it can be suitably determined by a person with ordinary skill in the art.

The screen printed paste is dried for 3 to 10 minutes under around 150° C. in an embodiment. The dried paste is fired at peak temperature of 450 to 900° C. in an embodiment, and 500 to 800° C. in another embodiment. Firing at a temperature lower than 900° C. offers an advantage of reducing damage to P—N junctions, decreasing susceptibility to the occurrence of destruction caused by thermal damage. Firing time in a furnace (from an entrance to an exit of a furnace) is for 10 seconds to 3 minutes in an embodiment, 30 seconds to 90 seconds in another embodiment. In an example of a desirable firing profile, the firing conditions are 3-60 seconds at 400° C. or higher and 2-35 seconds at 600° C. or higher.

### EXAMPLES

The invention is explained below using examples, but the invention is not limited to these examples.

### (I) Conductive Paste Materials

A conductive paste was prepared using the following materials.

Conductive powder: spherical silver powder (D50 2.5 μm as determined with a laser scattering-type particle size distribution measuring apparatus). The content of the conductive powder was set at 88 wt % based on the total weight of the inorganic components (conductive powder, glass frit and ZnO particles).

Glass frit: Glass frits A, B, C and D each having a different softening temperature were used for the glass frit. The softening temperatures (Ts) and compositions of the glass frits are shown in Table 1 below. The content of the glass frit was set at 6 wt % based on the total weight of the inorganic components.

Additional metal/metal oxide powder: ZnO particles with a specific surface area of 3.2 m²/g were used. The content of the ZnO particles was set at 6 wt % relative to the total weight of the inorganic components.

Organic binder: A mixture of ethyl cellulose and a solvent was used. The content of the organic binder was set at 15 wt % based on the total weight of the conductive paste.

TABLE 1

| | | | |
|---|---|---|---|
| Glass | Glass | Glass | Glass |
| frit A | frit B | frit C | frit D |

Glass softening temp. (Ts, ° C.)

| | 309 | 330 | 376 | 405 |
|---|---|---|---|---|
| SiO₂ | 12.80 | 12.83 | 12.97 | 18.89 |
| Al₂O₃ | 0.37 | 0.37 | 0.37 | 0.95 |
| PbO | 61.45 | 61.64 | 73.76 | 52.71 |
| PbF₂ | 24.74 | 24.79 | 12.53 | 24.73 |
| B₂O₃ | 0.00 | 0.00 | 0.00 | 1.92 |
| ZrO₂ | 0.37 | 0.37 | 0.37 | 0.48 |
| Li₂O | 0.18 | 0.00 | 0.00 | 0.21 |
| Na₂O | 0.09 | 0.00 | 0.00 | 0.11 |
| total | 100.00 | 100.00 | 100.00 | 100.00 |

### (II) Paste Preparation

Paste preparations was accomplished with the following procedure: The appropriate amount of organic binder was weighed then mixed with glass frit described above and ZnO powder in a mixing can for 15 minutes. Since Ag was the major part of the solids, it was added incrementally to ensure better wetting. When well mixed, the paste was repeatedly passed through a 3-roll mill for at progressively increasing pressures from 0 to 400 psi. The gap of the rolls was adjusted to 1 mil.

### (III) Electrode Preparation

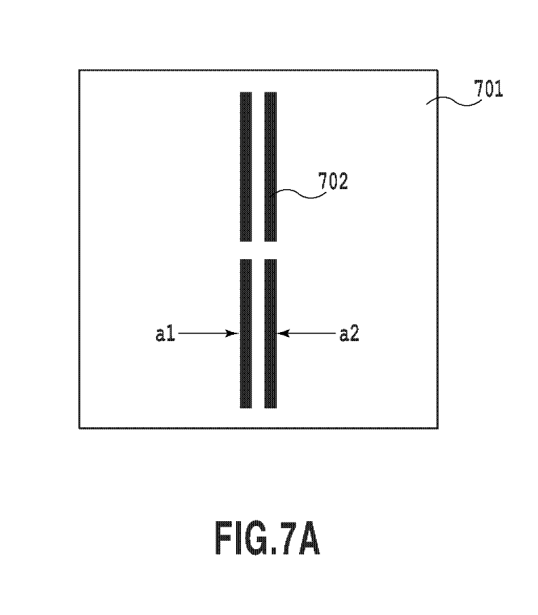

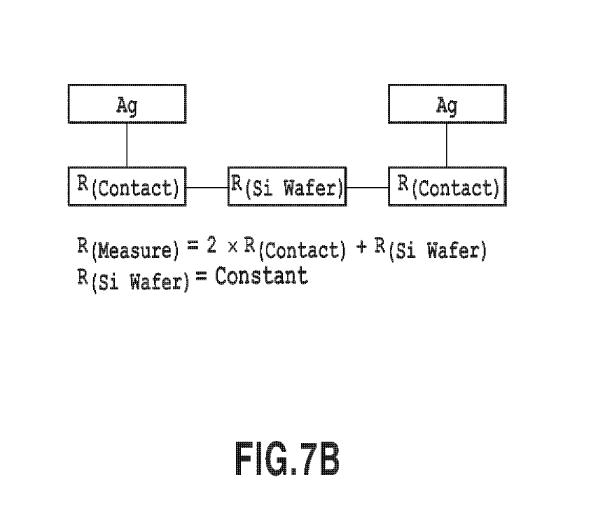

A conductive paste obtained by the aforementioned methods was screen printed on substrate 701 (25 mm×25 mm) having a 400 nm-thick silicon nitride (SiNₓ) layer on one n layer side of a p-type Si substrate with 0.2 mm thickness, to form a line pattern (length 10 mm, width 2 mm, thickness 10 μm) 702 (FIG. 7A). The distance between lines was 1 mm. The substrate and line pattern were dried for 5 minutes at 150° C. in a convection oven. The dried conductive paste was fired in an IR heating type of belt furnace (CF-7210, Despatch Industry) to obtain an electrode. The firing time was the time between the entrance and exit of the furnace, or 60 seconds. The belt speed during firing was 550 cpm. Firing profile was 22 seconds at over 400° C. and 6 seconds at over 600° C. and the peak temperature was 800° C.

### (IV) Measurement of Resistance

The resistance between the electrodes (resistance between pads, Ω) was measured using a source meter 2420, Keithley Instruments Inc.). As shown in FIG. 7A, the resistance between electrodes was the value measured between the two points a1 and a2, representing the shortest distance midway between the two electrodes. As shown in FIG. 7B, the measured resistance (R_{(Measure)}) between pads was the sum of the Si wafer resistance (R_{(Si Wafer)}) the resistance of the electrode itself and contact resistance (R_{(Contact)}) at the interface between the Si wafer and electrode. The electrode resistance is extremely low compare with other resistance so that it can be ignored. Because the same Si wafers were used, the resistance between the pads all had the same Si wafer resistance (R_{(Si Wafer)}) which can be constant. The magnitude of the resistance between pads (R_{(Measure)}) thus represents, that is, the magnitude of the contact resistance (R_{(Contact)}).

### (V) Results

The resistance between electrodes formed of the pastes with different glass softening points is shown in Table 2. In Comparative Example 1 using glass frit D with a softening point of 405° C., the resistance between electrodes was about 50 ohm, while in Examples 1 to 3 using glass frits A, B and C with lower softening points, the resistance between electrodes was 30 ohm or less.

TABLE 2

| | | | Resistance |
|---|---|---|---|
| | Glass | | between Pads |
| | frit | Ts (° C.) | (ohm) |
| Example 1 | A | 309 | 10.2 |
| Example 2 | B | 330 | 12.4 |
| Example 3 | C | 376 | 17.2 |
| Comparative | D | 405 | 49.9 |
| Example 1 | | | |

Next, the content of zinc oxide (ZnO) was investigated. The content of ZnO particles was varied, and conductive pastes (Examples 4-7) were prepared as in Example 1 using glass frit A (Ts 309° C.). Table 3 shows contents of Ag, glass frit and ZnO particle (wt % based on the total weight of the inorganic components) of the conductive pastes used in Examples 4-7. Using these conductive pastes having different ZnO particle contents, electrodes were formed by printing and firing on a 400 nm-thick silicon nitride layer. The firing condition was the same as in Example 1 above. The measured results for resistance between electrodes formed using the various conductive pastes are shown in Table 3. Regardless of the added amount of ZnO, the resistance between electrodes of the electrodes of Examples 4-7 was 30 ohm or lower in all cases of example 4-7. The resistance between electrodes was excellent especially in Examples 5 and 6, in which the ZnO particle content was 3 wt % and 5 wt %, respectively.

TABLE 3

| | | | | Resistance |
|---|---|---|---|---|
| | Ag | Glass Frit | ZnO | between Pads |
| | (wt %) | (wt %) | (wt %) | (ohm) |
| Example 4 | 93 | 7 | 0 | 24.5 |
| Example 5 | 91 | 7 | 3 | 10.3 |
| Example 6 | 88 | 6 | 5 | 10.5 |
| Example 7 | 82 | 6 | 12 | 20.0 |

The conductive paste used in Example 5 (glass frit A, Ts 309° C., ZnO particles 3 wt %) was also fired at different temperatures. As in Examples 4-7, the paste was printed on a 400 nm-thick silicon nitride layer. And then it was fired with two different peak temperatures, 780° C. and 820° C., to form electrodes. The resistance between electrodes after firing was measured as above. The results are shown in Table 3. Considering that the resistance between electrodes was 10.5 ohm in the case of Example 5 in which the peak firing temperature was 800° C., resistance between electrodes was 30 ohm or lower regardless of firing temperature in electrodes formed of a conductive paste containing a glass frit with softening point of 309° C. and 3 wt % of ZnO particles.

TABLE 4

| | | Resistance |
|---|---|---|
| | Peak Firing Temp. | between Pads |
| Electrode | (° C.) | (ohm) |
| Example 8 | 780 | 18.8 |
| Example 5 | 800 | 10.5 |
| Example 9 | 820 | 11.4 |

These results show that in an electrode formed of an electrode paste containing glass frit with a low softening point, fire-through can be achieved and the contact resistance with the semiconductor silicon substrate minimized even with a passivation layer 200 nm or more.

By containing a suitable amount of ZnO particles in the conductive paste, moreover, it is possible to further reduce the contact resistance of the semiconductor silicon substrate and the electrode. Contact resistance is also minimized regardless of firing temperature in an electrode containing ZnO particles and glass with a low softening point. The fact that low contact resistance is obtained regardless of firing temperature means that the electrode is not likely to be affected by differences of the firing condition or by differences of a furnace during the forming electrode, which is useful for providing a solar cell having stable and excellent electrical characteristics.

What is claimed is:

1. A method for forming a solar cell electrode, comprising the steps of:
applying a conductive paste comprising an organic binder and inorganic components comprising conductive powder and glass frit onto a passivation layer with at least 200 nm thickness formed on one surface or on both front and back surfaces of a silicon substrate, wherein the softening point of the glass frit is 395° C. or lower; and
firing the conductive paste applied onto the passivation layer.

2. The method for forming a solar cell electrode according to claim 1, wherein the content of the glass frit is 0.5 to 15 wt % based on the total weight of the inorganic components in the conductive paste.

3. The method for forming solar cell electrode according to claim 1, wherein the inorganic components comprises an additional metal/metal oxide powder which is selected from (a) a metal selected from Zn, Ti, Mn, Sn, Mo, In and Cu; (b) an oxide of the metal (a); and (c) a mixture thereof, in an amount of 0.5 to 15 wt % based on the total weight of the inorganic components in the conductive paste.

4. The method for forming solar cell electrode according to claim 3, wherein the inorganic components comprises 2-8 wt % of ZnO based on the total weight of the inorganic components in the conductive paste.

5. The method for forming a solar cell electrode according to claim 1, wherein a peak firing temperature in the firing step is 450 to 900°, and a firing time is 10 seconds to 3 minutes.

6. The method for forming a solar cell electrode according to claim 1, wherein the glass frit comprises either a lead (Pb) compound or a bismuth (Bi) compound.

7. The method for forming a solar cell electrode according to claim 6, wherein the glass frit comprises 60-92 wt % of PbO, 10-30 wt % of SiO₂, 0.1-2.0 wt % of Al₂O₃, and 0.1-2.0 wt % of ZrO₂ based on the total weight of the glass frit.

8. The method for forming a solar cell electrode according to claim 7, wherein the glass frit further comprises 0.01-20 wt % of K₂O, 0.01-10 wt % of Na₂O, and 0.05-5 wt % of Li₂O based on the total weight of the glass frit.

9. The method for forming a solar cell electrode according to claim 6, wherein the glass frit comprises 20-80 wt % of Bi₂O₃, 5-50 wt % of SiO₂, 0.01-20 wt % of BaO, 0.1-25 wt % of Al₂O₃, and 0.1-25 wt % of Ti₂O based on the total weight of the glass frit.

10. The method for forming a solar cell electrode according to claim 9, wherein the glass frit further comprises 0.01-20 wt % of K₂O, 0.01-10 wt % of Na₂O, and 0.05-5 wt % of Li₂O based on the total weight of the glass frit.

11. The method for forming a solar cell electrode according to claim 1, wherein the passivation layer comprises a silicon nitride (SiNₓ) layer.

12. A solar cell electrode formed by the method of claim 1.
